(19) United States
(12) Patent Application Publication
(10) Pub. No.: US 2009/0019692 A1
(43) Pub. Date: Jan. 22, 2009

(54) METHOD OF CUTTING SIGNAL WIRE PRESERVED ON CIRCUIT BOARD AND CIRCUIT LAYOUT THEREOF

(75) Inventors: Chih-Yi Huang, Kaohsiung City (TW); Hung-Hsiang Cheng, Kaohsiung City (TW)

Correspondence Address: J C PATENTS, INC., 4 VENTURE, SUITE 250, IRVINE, CA, 92618, US

(73) Assignee: Advanced Semiconductor Engineering, Inc., Kaohsiung (TW)

(21) Appl. No.: 12/142,107

(22) Filed: Jun. 19, 2008

(30) Foreign Application Priority Data
Jul. 19, 2007 (TW) 96126334

(51) Int. Cl. H05K 3/02

(52) U.S. Cl. 29/847

(57) ABSTRACT

A method of cutting signal wire preserved on circuit board applicable to a circuit layout is provided to reduce signal return loss induced by the preserved wires. The circuit layout has a plurality of preserved wires and a common contact electrically connected to the preserved wires. The cutting method is performed by cutting off one of the preserved wires and disconnecting a break part of the wire from the common contact.

### CROSS-REFERENCE TO RELATED APPLICATION

This application claims the priority benefit of Taiwan application serial no. 96126334, filed on Jul. 19, 2007. The entirety of the above-mentioned patent application is hereby incorporated by reference herein and made a part of specification.

### BACKGROUND OF THE INVENTION

1. Field of the Invention

The present invention generally relates to a circuit board, in particular, to a method of cutting signal wire preserved on circuit board and a circuit layout thereof.

2. Description of Related Art

In modern life with continuous technology progress, electronic products play an indispensable role in people's life. With the increasing demands on electronic products, manufacturers of electronic products have increased requirements on the chip package in electronic products. Therefore, how to improve the working efficiency and stability of chip package is an urgent problem to be solved. As a substrate for chip package, the circuit board will definitely affect the working efficiency and stability of chip package.

Generally, after the substrate of the circuit board is laminated, connection holes are formed on a surface of or inside the circuit board, next, wires are formed on the circuit board, and the formed wires can be turned on in the circuit board through the connection holes. In order to prevent the wires formed on the circuit board from being contaminated or damaged, a layer of mask material is coated on the circuit board. Generally, on a common circuit board, one contact (or pad) can transmit one signal, so there is merely one wire connected to the contact. However, in some circuit boards, due to the consideration of design cost, a circuit board is designed to carry at least two types of chips. Therefore, there may be two wires preserved on the circuit board to be connected to the contact, in which one wire is corresponding to the first type of chip, and the other wire is corresponding to the second type of chip. However, when the circuit board carries one type of chip, merely the wire corresponding to the type of chip is used, and the wire corresponding to the other type of chip is idle. The idle wire is still electrically connected to the substrate through the contact, thus easily causing signal return loss during transmission. Especially, when the transmitted signals are high-speed differential signals, the signal return loss generated by the idle wires is even severer.

### SUMMARY OF THE INVENTION

Accordingly, the present invention is directed to a method of cutting signal wire preserved on circuit board, which cuts off idle wires to reduce the signal return loss induced by the wires during signal transmission.

The present invention is further directed to a circuit layout, in which the idle wires are cut off to reduce the signal return loss induced by the wires during signal transmission.

The present invention provides a method of cutting a signal wire preserved on a circuit board, which is applicable to a circuit layout. The circuit layout includes a plurality of first preserved wires and a first common contact electrically connected to the first preserved wires. The cutting method is performed by cutting off a first wire in the first preserved wires and disconnecting a break part of the first wire from the first common contact.

In an embodiment of the present invention, a process of cutting off the first wire includes removing an end part of the first wire adjacent to the first common contact by laser.

In an embodiment of the present invention, the circuit layout further includes a plurality of second preserved wires and a second common contact electrically connected to the second preserved wires, and the cutting method further includes cutting off a second wire in the second preserved wires and disconnecting a break part of the second wire from the second common contact. Furthermore, a process of cutting off the second wire includes removing an end part of the second wire adjacent to the second common contact by laser.

The present invention provides a circuit layout fabricated by a cutting method, which is applicable to a circuit board. The circuit layout includes a carrier, a plurality of first preserved wires, and a first common contact. The carrier carries one of at least two types of chips. The first preserved wires are disposed on the carrier and around the chip. The first common contact is disposed on the carrier and is electrically connected to a first reversed wire in the first preserved wires except the cut off first wire.

In an embodiment of the present invention, the first reserved wire is corresponding to one type of chip, and the cut off first wire is corresponding to another type of chip.

In an embodiment of the present invention, the first reserved wire includes a bonding pad disposed at an end adjacent to the chip. In addition, the circuit layout further includes a first metal line electrically connected between the chip and the bonding pad in the manner of wire bonding.

In an embodiment of the present invention, the circuit layout further includes a protection layer covering the carrier and the first preserved wires, and the protection layer includes a cutting window for exposing the break part of the first wire.

In an embodiment of the present invention, the circuit layout further includes a plurality of second preserved wires and a second common contact. The second preserved wires are disposed on the carrier and around the chip. The second common contact is disposed on the carrier and is electrically connected to a second reserved wire in the second preserved wires except a cut off second wire.

In an embodiment of the present invention, the first reserved wire and second preserved wire include a differential pair.

In an embodiment of the present invention, the cut off first wire and the second wire include a differential pair.

In view of the above, in the method of cutting signal wire preserved on circuit board and the circuit layout thereof of the present invention, the idle wires are cut off to eliminate the signal return loss induced by the wires during signal transmission, so as to improve the stability of the signal.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a circuit layout according to an embodiment of the present invention.

FIG. 1B is a bottom view of a part area of the preserved wires in FIG. 1A before cutting.

FIG. 1C is a bottom view of a part area of the preserved wires in FIG. 1B after cutting.

FIG. 2A is a top view of a circuit layout according to an embodiment of the present invention.

FIG. 2B is a bottom view of a part area of the preserved wires in FIG. 2A before cutting.

FIG. 2C is a bottom view of a part area of the preserved wires in FIG. 2B after cutting.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

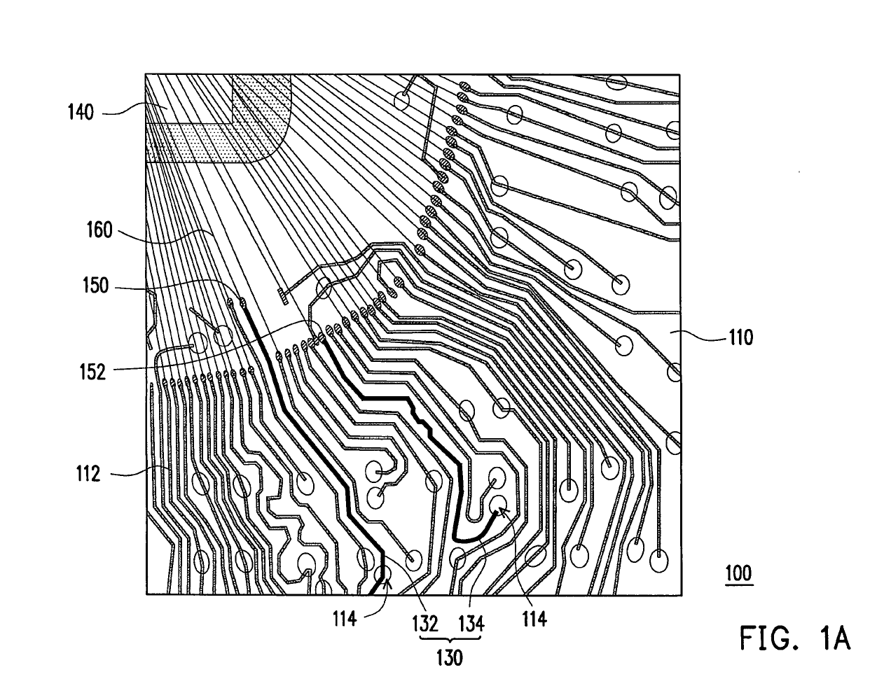

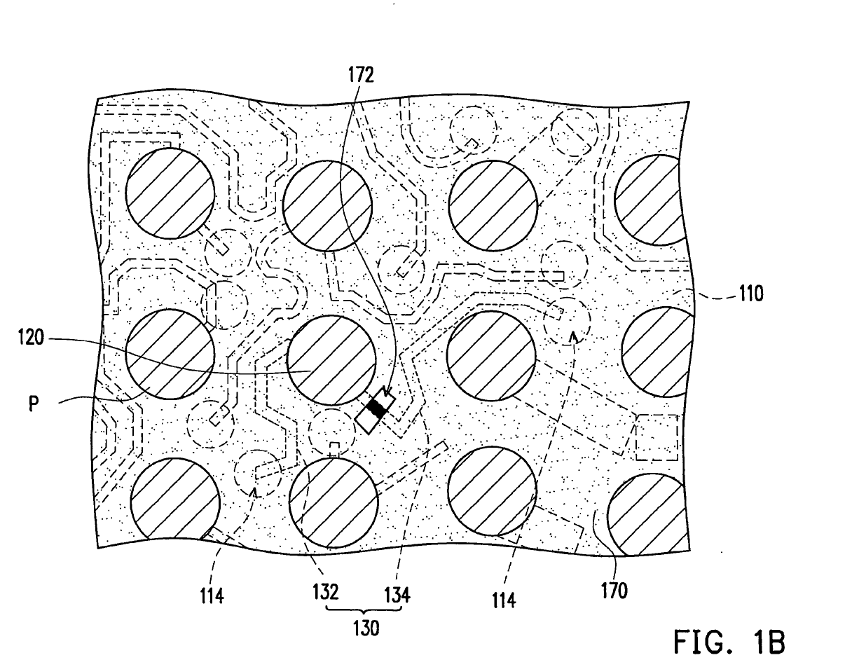

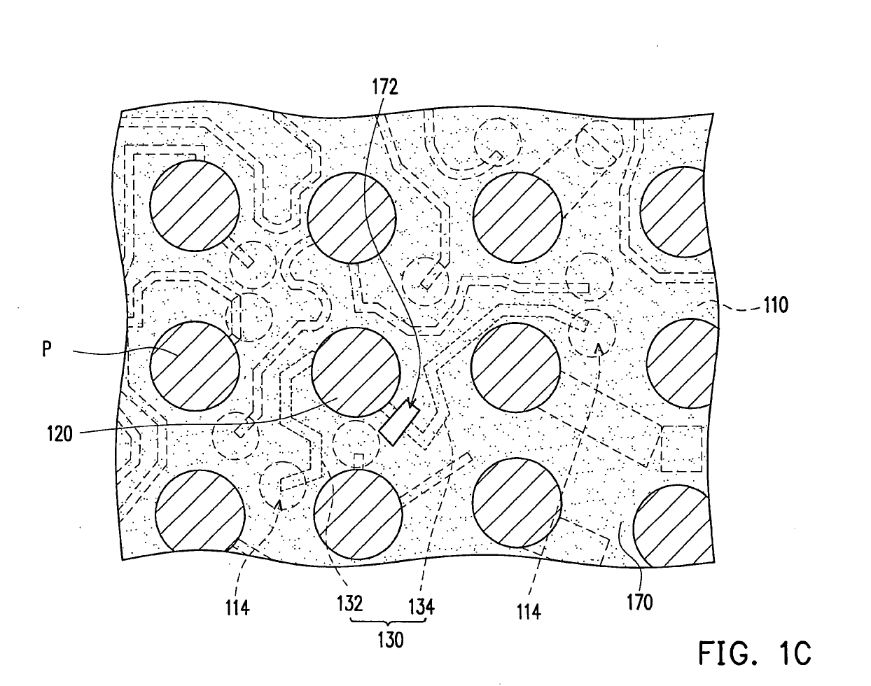

FIG. 1A is a top view of a circuit layout according to an embodiment of the present invention. FIG. 1B is a bottom view of a part area of the preserved wires in FIG. 1A before cutting. FIG. 1C is a bottom view of a part area of the preserved wires in FIG. 1B after cutting.

Referring to FIGS. 1A and 1B, a circuit layout 100 of a circuit board includes a carrier 110, a plurality of signal lines 112 disposed on the carrier 110 (see FIG. 1A), and a plurality of contacts P (see FIG. 1B, represented by a tilt line area) electrically connected to the signal lines 112. Among the signal lines 112, at least two are preserved wires 130 (represented by bold lines). Each of the preserved wires 130 are electrically connected to a common contact 120 in FIG. 1B via an individual connection hole 114 penetrating the carrier 110 and a wiring. The common contact 120 is electrically connected to an external electronic device through, for example, a solder ball, conductive adhesive, or other interfaces, so as to transmit electronic signals.

In this embodiment, in the preserved wires 130 on the carrier 110, one preserved wire 132 is preserved for being electrically connected to a first type of chip 140, and has a bonding pad 150 disposed at an end adjacent to the chip 140, such that the first type of chip 140 can electrically connect to the bonding pad 150 through at least one metal line 160 in the manner of wire bonding. Further, another preserved wire 134 is reserved to be electrically connected to a second type of chip (not shown), and has a bonding pad 152 disposed at an end adjacent to the second type of chip, such that the second type of chip can electrically connect to the bonding pad 152 through at least one metal line (not shown) in the manner of wire bonding. Materials of the preserved wires 130 and the common contact 120 are, for example, copper or other suitable conductive materials. In this embodiment, the circuit layout 100 of the circuit board further includes a protection layer 170(see FIG. 1B). The protection layer 170 covers the carrier 110, the connection holes 114, and the preserved wires 130 on the carrier 110, and has at least one cutting window 172 for exposing, for example, an end part of the preserved wire 134 adjacent to the common contact 120. A material of the protection layer 170 is a solder mask material, for example, polyimide and epoxy resin etc.

Next, referring to FIG. 1C, in this embodiment, when the first type of chip 140 is disposed on the carrier 110, the idle wire 134 (i.e., the cut off wire) in the preserved wires 130 can be cut off, so as to disconnect the wire 134 from the common contact 120. A process of cutting off the idle wire 134 includes removing an end part (i.e., an area exposed to the cutting window 172) or other suitable positions of the wire 134 adjacent to the common contact 120 by laser or etching. At this time, the common contact 120 is merely electrically connected to the reserved wire 132 in the preserved wires 130 except the cut off wire 134.

Accordingly, the cutting method of this embodiment is performed by cutting off the connection of the preserved wire 134 corresponding to the second type of chip and the common contact 120, that is, cutting off the idle wire (branch) in the circuit layout 100, and merely reserving the connection of the reserved wire 132 corresponding to the first type of chip 140 and the common contact 120. Therefore, the signal return loss generated during signal transmission in prior art can be eliminated.

Similarly, in another embodiment, when the second type of chip is disposed on the carrier, the preserved wire corresponding to the first type of chip is cut off, and merely the connection of the reserved wire corresponding to the second type of chip and the common contact is reserved.

### Second Embodiment

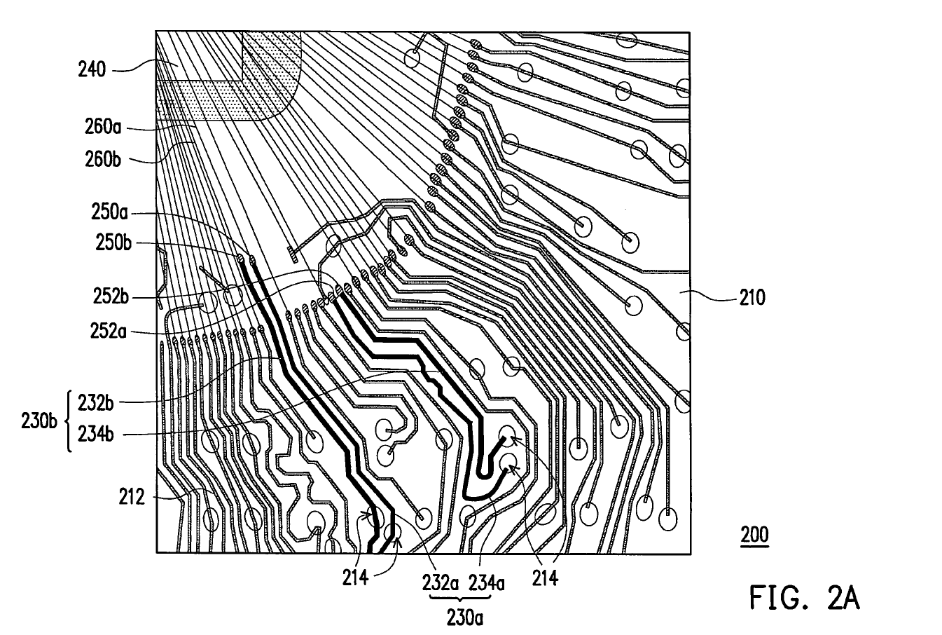

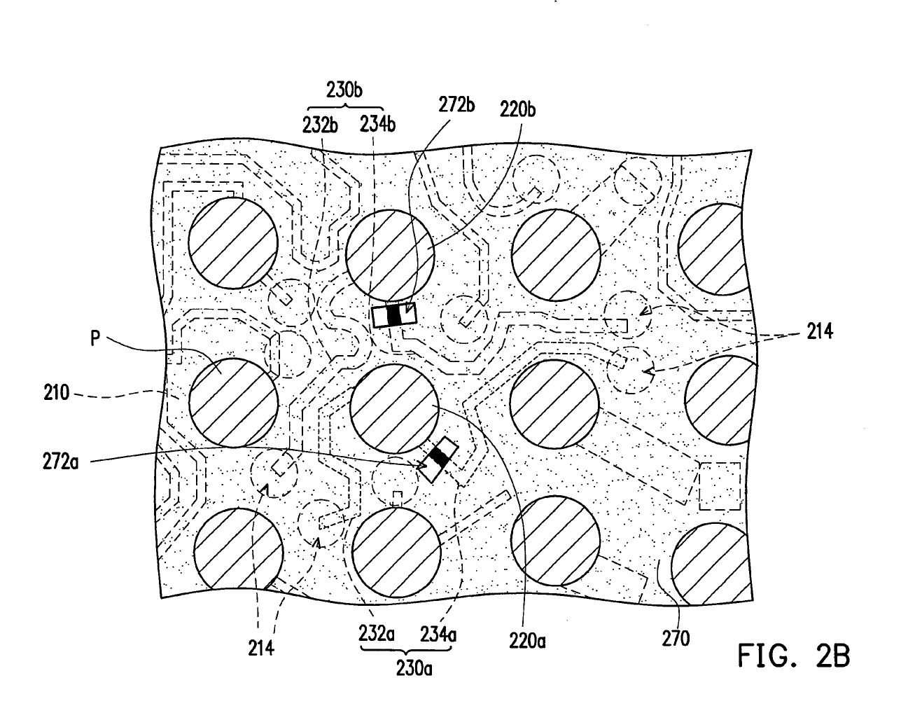

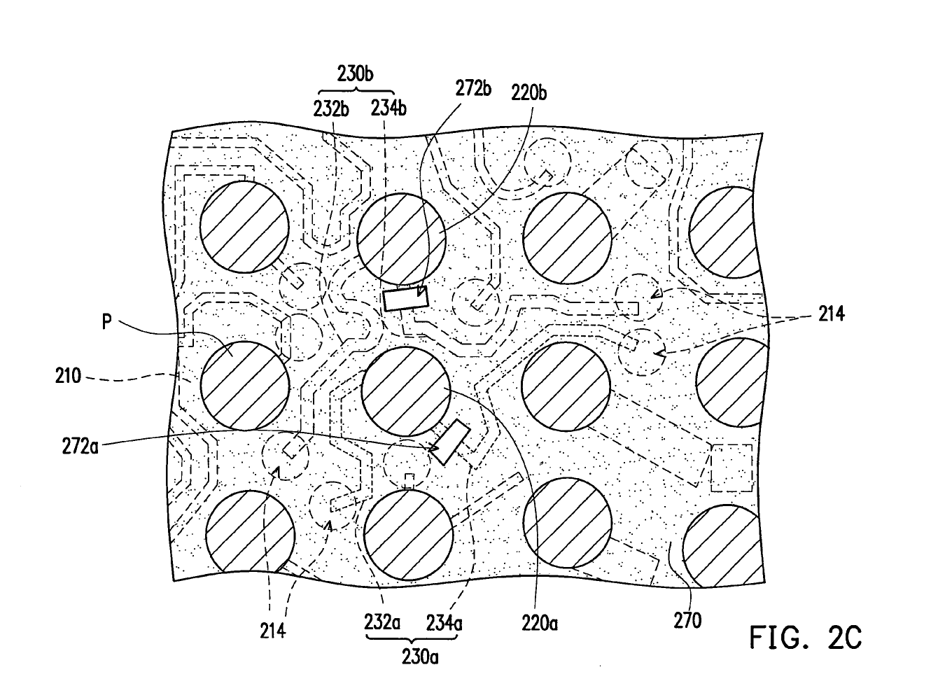

FIG. 2A is a top view of a circuit layout according to an embodiment of the present invention. FIG. 2B is a bottom view of a part area of the preserved wires in FIG. 2A before cutting. FIG. 2C is a bottom view of a part area of the preserved wires in FIG. 2B after cutting.

The difference between this embodiment and the first embodiment lies in that, when signal lines 212 of the circuit layout 200 includes a differential pair 232a, 232b, in order to prevent the differential signal from being affected by the idle preserved wires (another pair of differential signal wires 234a, 234b), the present invention cuts the idle preserved wires on the circuit board to eliminate the signal return loss. In the description hereinafter, the difference is distinguished by the first and the second preserved wires, and the rest content is substantially the same as that of the first embodiment. Referring to FIGS. 2A and 2B, a circuit layout 200 of a circuit board includes a carrier 210, a plurality of signal lines 212 disposed on the carrier 210 (see FIG. 2A), and a plurality of contacts P (see FIG. 2B) electrically connected to the signal lines 212. Among the signal lines 212, at least two are first preserved wires 230a, and at least two are second preserved wires 230b (represented by bold lines). The first preserved wires 230a and the second preserved wires 230b are electrically connected to a first common contact 220a and a second common contact 220b in FIG. 2B respectively via an individual connection hole 214 penetrating the carrier 210 and a wiring.

In this embodiment, in the first preserved wires 230a on the carrier 210, one first preserved wire 232a is preserved for being electrically connected to a first type of chip 240, and has a bonding pad 250a disposed at an end adjacent to the first type of chip 240, such that the first type of chip 240 can electrically connect to the bonding pad 250a through at least one first metal line 260a in the manner of wire bonding. Further, another first preserved wire 234a is preserved to be electrically connected to the second type of chip, and has a bonding pad 252a disposed at an end adjacent to the second type of chip (not shown), such that the second type of chip can electrically connect to the bonding pad 252a through at least one metal line (not shown) in the manner of wire bonding. Similarly, in the second preserved wires 230b on the carrier 210, one second preserved wire 232b is preserved to be electrically connected to the first type of chip 240, and has a bonding pad 250b disposed at an end adjacent to the first type of chip 240, such that the first type of chip 240 can electrically connect to the bonding pad 250b through at least one second metal line 260b in the manner of wire bonding. Further, another second preserved wire 234b is preserved to be electrically connected to the second type of chip, and has a bonding pad 252b disposed at an end adjacent to the second type of chip, such that the second type of chip can electrically connect to the bonding pad 252b through at least one metal line (not shown) in the manner of wire bonding. In this embodiment, the circuit layout 200 of the circuit board further includes a protection layer 270 (see FIG. 2B) thereon. The protection layer 270 covers the carrier 210, the connection holes 214 on the carrier 210, the first preserved wires 230a, and the second preserved wires 230b, and has at least one first cutting window 272a and at least one second cutting window 272b. The first cutting window 272a exposes, for example, an end part of the first preserved wire 234a adjacent to the first common contact 220a, and the second cutting window 272b exposes, for example, an end part of the second preserved wire 234b adjacent to the second common contact 220b.

Next, referring to FIG. 2C, in this embodiment, when the first type of chip 240 is disposed on the carrier 210, the idle wire 234a (i.e., the cut off first wire) of the first preserved wires 230a can be cut off, so as to disconnect the first wire 234a from the first common contact 220a, and the idle wire 234b (i.e., the cut off second wire) of the second preserved wires 230b can be cut off, so as to disconnect the second wire 234b from the second common contact 220b. A process of cutting off the first wire 234a includes removing an end part (i.e., an area exposed to the first cutting window 272a) or other suitable positions of the first wire 234a adjacent to the first common contact 220a by laser or etching. Similarly, a process of cutting of the second wire 234b includes removing an end part (i.e., an area exposed to the second cutting window 272b) or other suitable positions of the second wire 234b adjacent to the second common contact 220b by laser or etching.

Accordingly, the cutting method of this embodiment is performed by cutting off the first preserved wire 234a and the second preserved wire 234b corresponding to the second type of chip, that is, cutting of the connection of the idle wires (branch) in the circuit layout 200 and the common contact, and merely reserving the connection of the first reserved wire 232a and the second reserved wire 232b corresponding to the first type of chip 240 with the first common contact 220a and second common contact 220b respectively. Therefore, the signal return loss generated during differential signal transmission in prior art can be eliminated.

In view of the above, in the method of cutting signal wire preserved on circuit board of the present invention and the circuit layout thereof, the idle wires (branch) in the circuit layout are cut off, and merely the connection of the reserved wires corresponding to the type of chip carried on the carrier and common contacts is reserved. Therefore, the signal return loss generated by branches in conventional package structure is eliminated, so as to improve the stability of the signal.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of cutting signal wire preserved on circuit board, applicable for a circuit layout comprising a plurality of first preserved wires and a first common contact electrically connected to the first preserved wires, the method comprising:
cutting off a first wire in the first preserved wires, and disconnecting a break part of the first wire from the first common contact.

2. The cutting method according to claim 1, wherein a process of cutting off the first wire comprises removing an end part of the first wire adjacent to the first common contact by laser.

3. The cutting method according to claim 1, wherein the circuit layout further comprises a plurality of second preserved wires and a second common contact electrically connecting the second preserved wires, and the method further comprises:
cutting off a second wire in the second preserved wires, and disconnecting a break part of the second wire from the second common contact.

4. The cutting method according to claim 3, wherein a process of cutting off the second wire comprises removing an end part of the second wire adjacent to the second common contact by laser.

5. A circuit layout fabricated by the cutting method according to claim 1, applicable to a circuit board, comprising:
a carrier, for carrying one of at least two types of chips;
a plurality of first preserved wires, disposed on the carrier and around the chip; and
a first common contact, disposed on the carrier, and electrically connected to a first reserved wire in the first preserved wires except the cut off first wire.

6. The circuit layout according to claim 5, wherein the first reserved wire is corresponding to one type of chip, and the cut off first wire is corresponding to another type of chip.

7. The circuit layout according to claim 5, wherein the first reserved wire has a bonding pad at an end adjacent to the chip.

8. The circuit layout according to claim 7, further comprising a first metal line, electrically connected between the chip and the bonding pad in the manner of wire bonding.

9. The circuit layout according to claim 5, further comprising a protection layer, covering the carrier and the first preserved wires, wherein the protection layer comprises a cutting window for exposing the break part of the first wire.

10. The circuit layout according to claim 5, further comprising:
a plurality of second preserved wires, disposed on the carrier and around the chip; and
a second common contact, disposed on the carrier, and electrically connected to a second reserved wire in the second preserved wires except a cut off second wire.

11. The circuit layout according to claim 10, wherein the second reserved wire is corresponding to one type of chip, and the cut off second wire is corresponding to another type of chip.

12. The circuit layout according to claim 10, wherein the second reserved wire comprises a bonding pad at an end adjacent to the chip.

13. The circuit layout according to claim 12, further comprising a second metal line, electrically connected between the chip and the bonding pad in the manner of the wire bonding.

14. The circuit layout according to claim 10, further comprising a protection layer, covering the carrier and the second preserved wires, wherein the protection layer comprises a cutting window for exposing a break part of the second wire.

15. The circuit layout according to claim 10, wherein the first reserved wire and the second reserved wire comprise a differential pair.

16. The circuit layout according to claim 10, wherein the cut off first wire and second wire comprise a differential pair.
